(19) United States
(12) Patent Application Publication
(10) Pub. No.: US 2026/0016540 A1
(43) Pub. Date: Jan. 15, 2026

(54) AUTOMATIC BATTERY SYSTEM TESTING AND REPORTING SYSTEM AND METHODS

(71) Applicant: A123 Systems LLC, Novi, MI (US)

(72) Inventors: Stefan Rabas, Ostendorf (DE); Felix Roemer, Neufahrn (DE); Kaveh Panahi, Stuttgart (DE)

(21) Appl. No.: 19/264,723

(22) Filed: Jul. 9, 2025

Related U.S. Application Data
(60) Provisional application No. 63/669,142, filed on Jul. 9, 2024.

(51) Int. Cl. G01R 31/36; G01R 31/3842; H01M 10/42

(52) U.S. Cl. CPC G01R 31/3644; G01R 31/3842; H01M 10/4285; H01M 2010/4271; H01M 2220/20

(57) ABSTRACT

Systems and methods are provided for an automatic battery test system for a battery system. The automatic battery test system includes a switch matrix coupled to the battery system, a peripheral instrument coupled to the battery system via the switch matrix, a communication interface coupled to the switch matrix, and a computing system coupled to the switch matrix via the communication interface.

### CROSS-REFERENCE TO RELATED APPLICATIONS

The present application claims priority to U.S. Provisional Application No. 63/669,142 entitled “AUTOMATIC BATTERY SYSTEM TESTING AND REPORTING SYSTEM AND METHODS”, and filed on Jul. 9, 2024. The entire contents of the above listed application is hereby incorporated by reference for all purposes.

### FIELD

The present description relates generally to a system and methods for testing and reporting a performance of a battery system.

### BACKGROUND AND SUMMARY

A battery system may include a plurality of battery cells coupled in parallel and in series in addition to other components such as, but not limited to, temperature control systems, protection circuits, and a battery management system (BMS). The battery system may undergo testing at multiple stages during the product lifetime, for example while in the manufacturing facility, after being shipped to a user, and in general to evaluate the battery system performance. Conventional battery system testing methods include manual data collection followed by expert analysis. The conventional battery system testing methods may be both time consuming and prone to the human error and variability, leading to inconsistencies between test operators and decreased reliability of the results. Additionally, the conventional testing methods may not dynamically test a functionality of the battery system. Current automatic solutions may be implemented at a manufacturing facility (e.g., end-of-line (EOL) testing) however, EOL solutions are large and heavy and not practical for deploying to a customer facility or a user in the field as demanded over the lifetime of the battery system.

The inventors herein have identified the above problems and have determined solutions to at least partially solve them. In one example, an automatic battery test system for a battery system comprises a switch matrix configured to couple to the battery system and comprised of rows and columns of electrical connections and switches configured to re-route power and signals through the electrical connections, a peripheral instrument coupled to the battery system via the switch matrix, a communication interface coupled to the switch matrix; and a computing system coupled to the switch matrix via the communication interface. The automatic battery testing system may allow an operator who is not trained in all procedures and data interpretation for each battery test to perform testing of battery systems. Additionally, the testing may be performed in a uniform and repeated manner across all operators. Further the automatic battery test system may be portable, allowing battery system testing to be reliably performed in the field, away from a lab or heavy manufacturing setting.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

FIG. 1 shows an example of a conventional battery testing system.

FIG. 2 shows a diagram of an automatic battery testing system.

FIG. 3A shows a diagram of a switch matrix.

FIG. 3B shows a simplified diagram of a plurality of switch matrices connected in parallel.

FIG. 4 shows a flowchart of an example of a method of an automatic battery testing system.

FIG. 5. shows a diagram of a switch matrix configured to test a low voltage current of a battery system.

FIG. 6 shows a graph of voltage as a function of time collected during testing with the automatic battery testing system.

FIG. 7 shows a graph of current as function of time for current pulses at a BMS of an automotive battery system.

### DETAILED DESCRIPTION

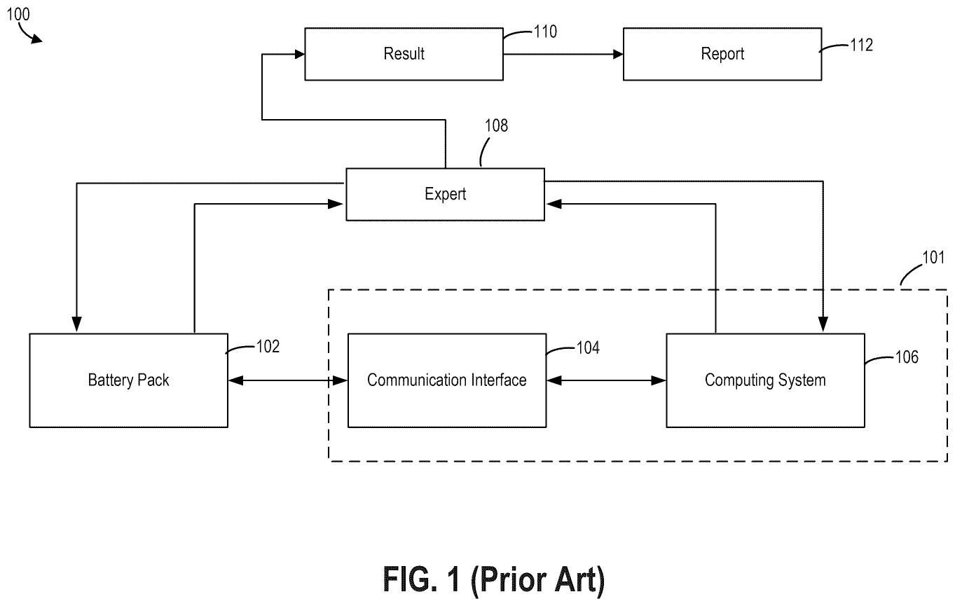

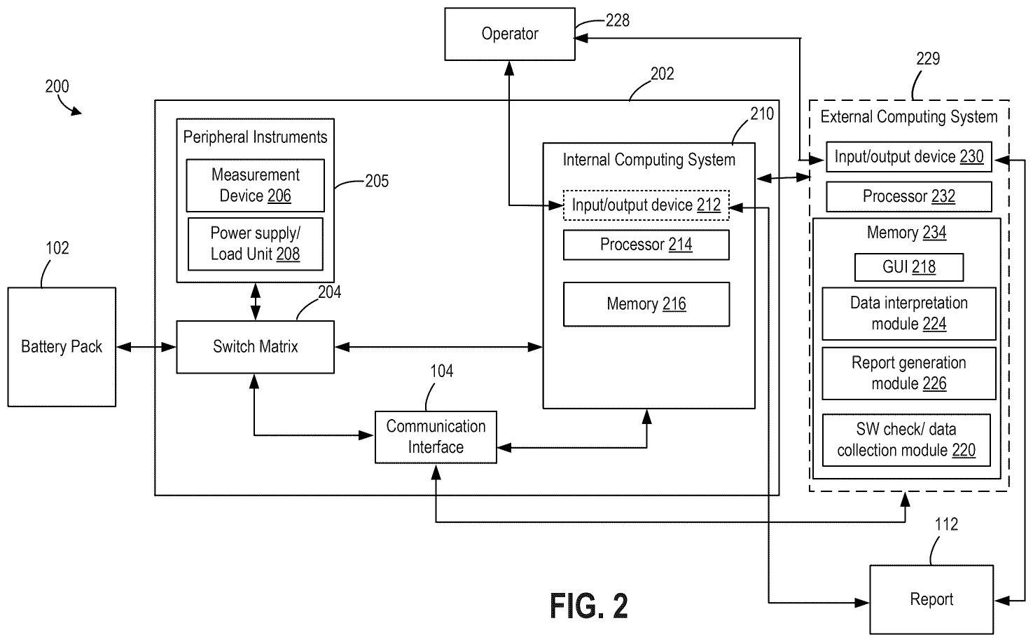

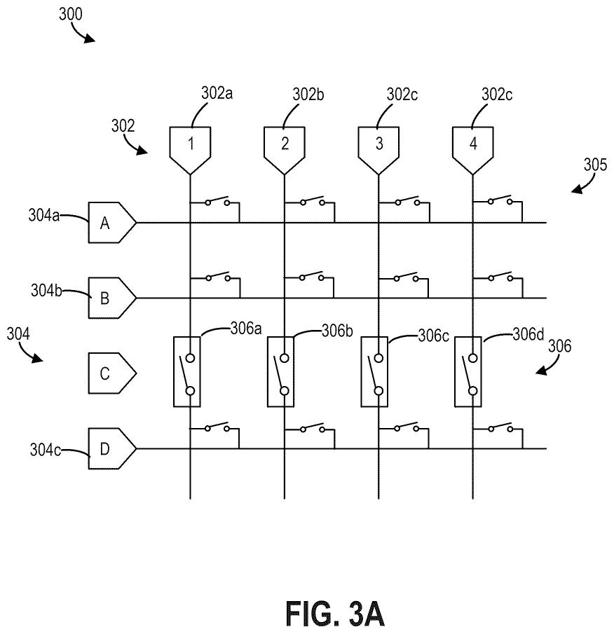

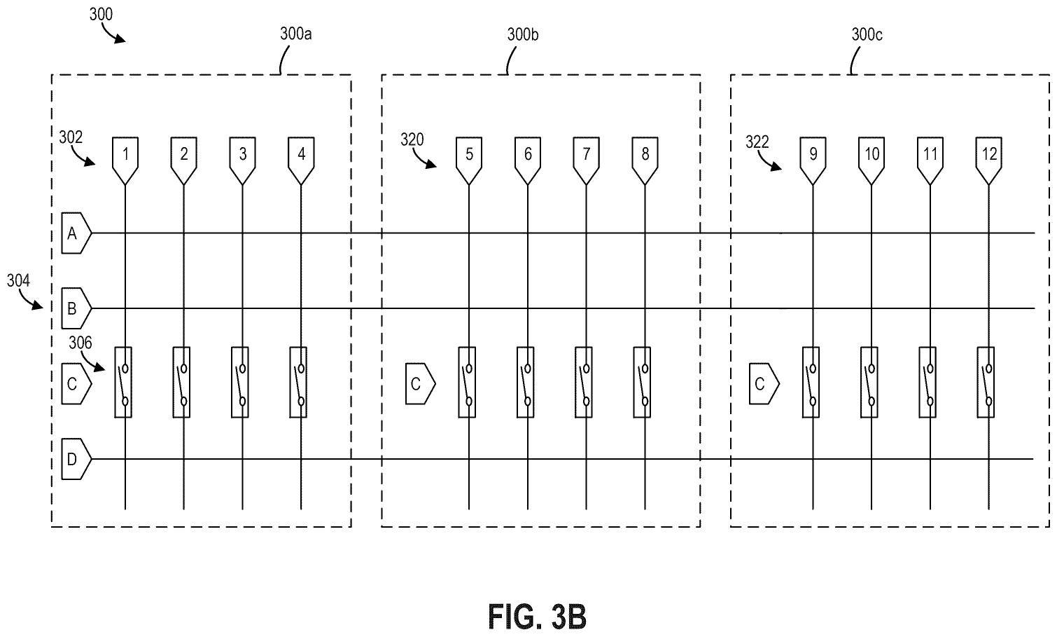

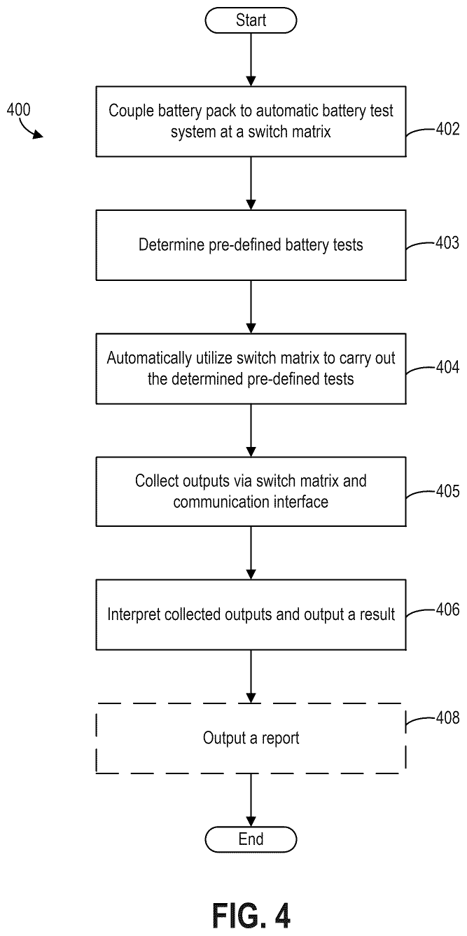

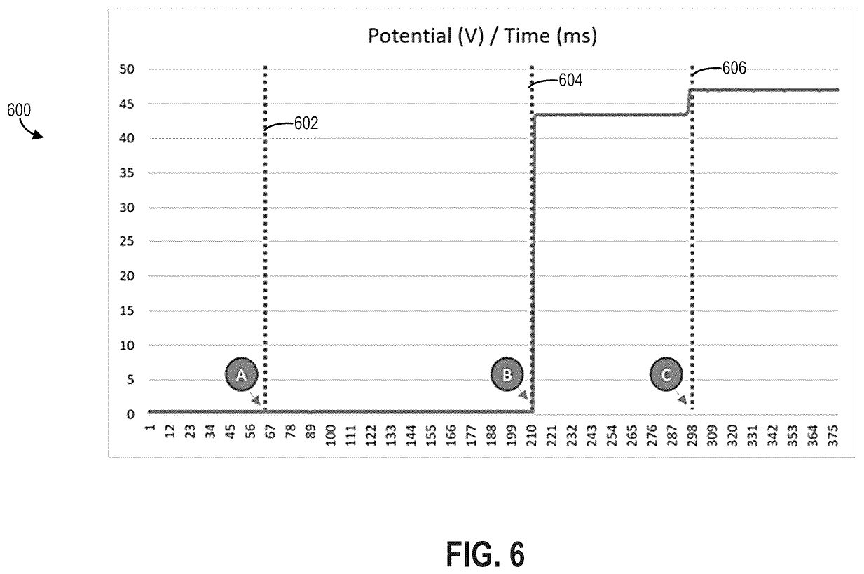

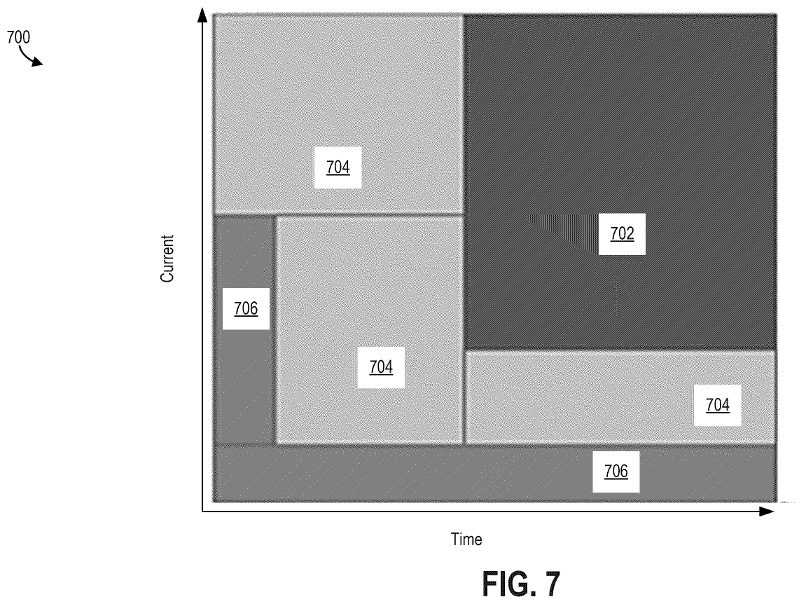

The following description relates to systems and methods for automatic battery system testing. The battery system may include a plurality of cells coupled in parallel and in series and a battery management system (BMS) configured to control components of the battery system. Conventionally, test systems for determining that each component of the battery system hardware (e.g., the battery cells) as well as software (e.g., instructions stored on the BMS) is functioning as expected demand multiple manual measurements performed and analyzed by an expert user. An example of a conventional battery system test system is shown in FIG. 1. An automatic battery test system as shown in FIG. 2 may overcome at least some of the shortcomings of the conventional battery system test system. The automatic battery test system may perform a plurality of hardware and software tests demanded for a battery system. Multiplexing of communication with components of the battery system may be facilitated with a switch matrix as shown in FIG. 3A, configured to couple the battery system to peripheral instruments of the automatic battery test system and to a computing system. A number of components multiplexed may be increased by combining multiple switch matrices in parallel as shown in FIG. 3B. The automatic battery test system may be operated according to a method, an example of which is shown as a flowchart in FIG. 4. In some examples, the automatic battery test system may be used to test an automotive battery system. In such examples, a pre-charge circuit of the automotive battery system or a crash response of the automotive battery system may be tested as described further with respect to FIGS. 6 and 7. It is understood that the examples of FIGS. 6-7 are non-limiting examples of tests of automotive battery systems, and many other types of tests may be performed on automotive battery systems using the automatic battery test system.

Turning now to FIG. 1, it shows a diagram 100 depicting an example of a conventional battery test system 101. The conventional battery test system 101 may be communicatively coupled to a battery system 102 via a communication interface 104. Communication may occur via a communication protocol. For example, the communication protocol may be a serial communication protocol. As a further example, the communication protocol may be specialized communication protocol used for an application, such as automotive applications. For example, the communication protocol may be over a local interconnect network (LIN) protocol, controller area network (CAN) protocol, Modbus, FlexRay protocol, or other protocols. Communication interface 104 may be an interface configured to convert the communication from the battery system 102 (e.g., CAN/LIN protocols) into data readable via a computing system 106 over a conventional computer communication interface such as Ethernet or USB. An expert user 108 may instruct the computing system to collect the desired information from the battery system 102 regarding functionality of instructions of the battery system 102 stored on the BMS. The expert user 108 may then compile and analyze the output of the computing system.

To determine functionality of battery system hardware, the expert user 108 may use a tool such as a multimeter and/or portable power source/load to make physical connections to a plurality of different components of the battery system. The tools may provide quantitative measurements that are collected and recorded by the expert user 108. The expert user may then analyze the collected information from the computing system and from the battery system hardware to determine a result 110. As one example the result 110 may be a determination as to whether the battery system is functioning within normal operating parameters or not. The result may further include a report, the report including all of the data collected and analysis performed by the expert user.

In this way, the expert user 108 may be central to operating the conventional battery test system 101. The expert user 108 may know how to perform the manual hardware tests and collect resulting measurements, what information to collect from the battery system software, accurately record and report the information, and analyze the data to determine a result. The testing of the battery system 102 using the conventional battery test system 101 is therefore subject to a level of expertise and training of the user, possible error of the user. Further, a time demanded to perform battery testing using the conventional battery test system 101 is further limited by a speed of the expert user 108.

An automatic battery test system, such as automatic battery test system 202 as shown in diagram 200 FIG. 2 does not demand an expert user. By automatically collecting and analyzing both software and hardware performance of battery system 102, an operator merely initializes a test and may read a pass/fail result. Diagram 200 may include some of the same components as diagram 100, such components are numbered the same and are not reintroduced.

Communication interface 104 of automatic battery test system 202 may communicate with battery system 102 using CAN/LIN or similar protocol via a switch matrix 204. Switch matrix 204 may include a matrix of electrical connections adapted to electrically couple components of the battery system 102 with peripheral instrument 205. In this way, an operator may communicatively couple automatic battery test system 202 to a single connection of battery system 102 and over that single connection, a plurality of signal sources of battery system 102 may be tested using peripheral instrument 205.

Peripheral instrument 205 may be coupled to the plurality of signals from the battery system 102 via switch matrix 204. Peripheral instrument 205 may include instruments adapted to test integrity of hardware and/or software components of battery system 102. Peripheral instrument 205 may be further adapted to test a performance or health of active material of battery system 102. In this way components of battery system 102 such as hardware and communication connections may be automatically tested by automatic battery test system 202.

As one example, peripheral instrument 205 may include a measurement device 206. Measurement device 206 may include a multimeter. The multimeter may be a high-precision digital multimeter. The multimeter may allow for measurement of resistance, potential, current or other parameters across components of battery system 102. Increased resistance may be indicative of degradation and/or defects of battery system 102. Additionally or alternatively, measurement device 206 may include a high potential (e.g., hipot) tester adapted to pressure test insulating components of battery system 102. Measurement devices 206 may also dynamically test battery system 102 via switch matrix 204. For example, automatic battery test system 202 may briefly activate (e.g., turn on) battery system 102 and measure a resulting output voltage, thereby evaluating a pre-charge function and electronic switch conditions of battery system 102.

In some embodiments, peripheral instrument 205 may additionally or alternatively include a power supply/load unit 208. Power supply/load unit 208 coupled to a plurality of signal sources via switch matrix 204 may enable automatic battery test system 202 to actively charge and discharge battery system 102. In this way, automatic battery test system 202 may be adapted to determine a state of health (SOH) of battery system 102 and may do so using repeatable charging and discharging protocols which are configured to not further degrade battery system 102.

Turning briefly to FIGS. 3A-3B an example of a switch matrix 300 is shown. Switch matrix 300 may be an example of switch matrix 204 of FIG. 2. Switch matrix 300 may be 4×N matrix including electrical connections arranged in columns 302 and rows 304 and a plurality of switches including node switches 305 and line switches 306. N may be at least four. Further, a number of columns of the switch matrix may be greater than or equal to a number of rows of the switch matrix. As one example, N may be equal to four and switch matrix 300 may be a 4×4 matrix as shown in FIG. 3A. In further examples, N may be greater than four. As one example, electrical connections of column 302 may each be configured to receive a signal from a battery component of a battery system such as battery system 102, couple to inputs and outputs of a peripheral instrument, such as peripheral instrument 205, or couple to battery communications. Electrical connections of column 302 may include a first electrical connection 302a, a second electrical connection 302b, a third electrical connection 302c, and a fourth electrical connection 302d. Rows 304 may include a first electrical connection 304a, a second electrical connection 304b, and a third electrical connection 304c. Rows 304 may act as a binary unit system (BUS) to transfer signals between the components coupled to electrical connections of columns 302. A plurality of node switches 305 may include a switch positioned at each intersecting node between an electrical connection of columns 302 and an electrical connection of row 304. When all of the plurality of node switches 305 are open, components of columns 302 are not coupled to rows 304. Selectively opening and closing individual node switches of the plurality of node switches 305 may route desired connections between the components coupled to columns 302 via the BUSes of rows 304.

Additionally, a row of rows 304 may include line switches 306. Line switches 306 may include first line switch 306a, second line switch 306b, third line switch 306c, and fourth line switch 306d. Each line switch of line switches 306 may be positioned in-line with an electrical connection of columns 302. As one examples, line switches 306 may be positioned in a row of rows 304 between second electrical connection 304b and third electrical connection 304c. In this way, opening and closing line switches 306 may ensure continuity of the electrical connections of columns 302.

In some examples, additional columns may be desired for testing of additional battery components or coupling to additional peripheral instruments. In such examples, switch matrix 300 may include a plurality of matrices coupled in parallel. An example of switch matrix 300 including a plurality of matrices is shown in FIG. 3B. FIG. 3B shows a first switch matrix 300a, a second switch matrix 300b, and a third switch matrix 300c. Node switches 305 of first switch matrix 300a, second switch matrix 300b, and third switch matrix 300c are present but not shown for clarity. First switch matrix 300a may include columns 302, second switch matrix 300b may include second columns 320, third switch matrix 300c may include third columns 322. Each of the first, second, and third columns 302, 320, and 322 may each include four electrical connections. In this way, twelve different connections between battery components or peripheral instruments may be established to switch matrix 300. Each electrical connection of columns 302 may include a line switch 306 as described above with respect to FIG. 3A. Rows 304 may extend between each switch matrix 300 of the plurality of matrices. In this way, additional battery components may be coupled to the automatic battery test system in different configurations via rows 304 by opening and closing node switches 305 on intersecting nodes of first, second, and third columns 302, 320, and 322 with rows 304. FIG. 3B shows switch matrix 300 including three switch matrices. It is understood that switch matrix 300 may include greater or fewer switch matrices. A number of switch matrices included in automatic battery test system 202 may depend on a number of battery components and/or peripheral instruments to be coupled to the automatic battery test system 202.

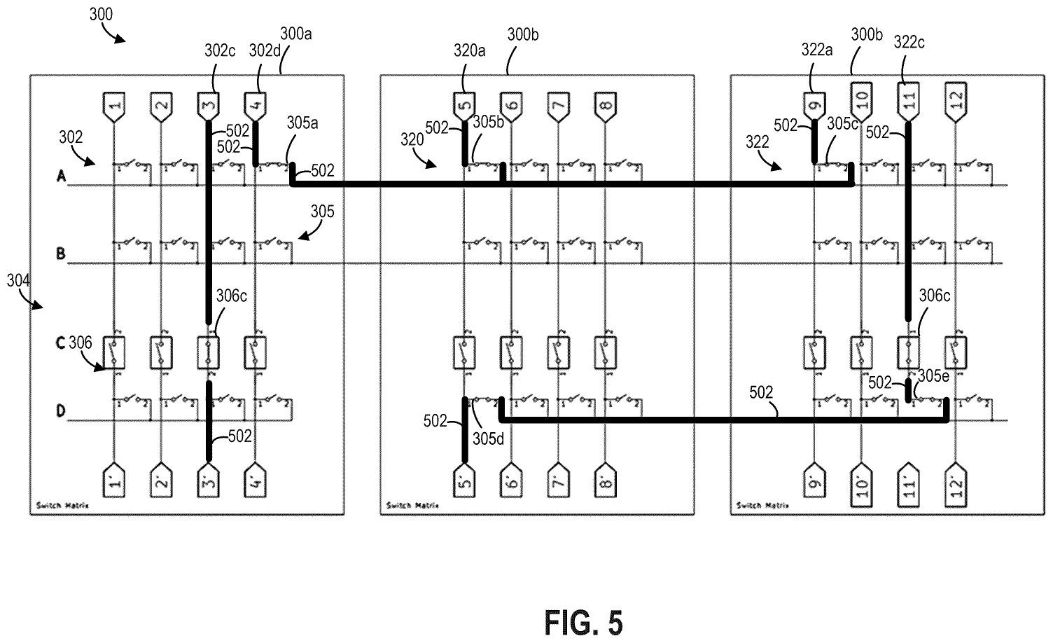

As a non-limiting example, FIG. 5 shows a switch matrix 300 of FIG. 3B configured to re-route a low voltage power supply line from a BMS (e.g., a BMS of battery system 102) into a current measurement device for consumption evaluation. Bold lines 502 indicate a flow current through switch matrix 300 in the configuration. A third column 302c of first switch matrix 300a may be coupled a 12v supply of a battery system. A third line switch 306c may be in a closed position to ensure continuity of the 12v power supply signal. A fourth column 302d of first switch matrix may be coupled to a 12v ground connection of the battery system, a first column 320a of second switch matrix 300b may be coupled to a negative terminal of the battery system at a first end (e.g., 5) and to ground at a second end (e.g., 5′), a first column 322a of third switch matrix 300c may be coupled to a measurement device positive terminal, and a third column 322c of third switch matrix 300c may be coupled to a measurement device negative terminal.

Node switches of the plurality of node switches 305 may be selectively closed to re-route the 12v power supply to the measurement device. A first node switch 305a, second node switch 305b, third node switch 305c may each be closed. By closing the node switch the 12v ground, and negative battery terminal are each coupled to the measurement device positive terminal by BUS A. Additionally, a fourth node switch 305d, fifth node switch 305e as well as line switch 306c of third switch matrix 300c may be closed to couple the measurement device negative terminal to a ground of the battery system via BUS D. In this way, power consumption of the battery system may be evaluated.

Returning now to FIG. 2, automatic battery test system 202 may include an internal computing system 210. Switch matrix 204 may be coupled to internal computing system 210. Internal computing system 210 may be a controller of switch matrix 204, configured to selectively open and close line switches and node switches of switch matrix 204 to re-route battery signal and power as demanded for tests of the battery system 102. Internal computing system 210 may include, a processor 214, memory 216, and optionally and input/output device 212. Additionally or alternatively, an external computing system 229 may be communicatively coupled to internal computing system 210 and/or to communication interface 104. External computing system 229 may include an input/output device 230, a processor 232, and memory 234. In one example, operator 228 may operate automatic battery test system 202 using input/output device 212 of internal computing system 210. In an alternate example, operator 228 may interact operate automatic battery test system 202 using external computing system 229. External computing system 229 may be a separate system such as desktop computer, laptop computer, tablet computer or the like and may be communicatively coupled, via a cable or wirelessly, to automatic battery test system 202 via communication interface 104 or via an output of internal computing system 210. In some examples, operator 228 may interact with both internal computing system 210 and external computing system 229 to operate automatic battery test system 202.

Input/output device 212 and input/output device 230 may each be configured to receive data from input sources and output data to output sources, thereby serving as an interface between the input sources, the output sources. The internal computing system 210 and/or external computing system 229 may receive input data from a user input device such as a keyboard, mouse, microphone, touch screen/touch pad. In some examples, input/output device 212 may be simplified compared to input/output device 230. For example, input/output device 212 may be a plurality of buttons configured to select an option and execute or stop a selected option, while input/output device 212 may be a full keyboard and/or touch screen display. The input/output device 212 and input/output device 230 may output data to one or more user output devices such as a display, a touch screen, speakers, and/or other such output devices that may be used to output data in a format understandable to a user. As such, in some examples the processor 214 of internal computing system 210 and/or processor 232 may of external computing system 229 may execute stored instructions using information from the input/output device 212 or input/output device 230 based on execution of the stored instructions.

Processor 214 and processor 232 may each execute instructions stored in memory. Memory 216 or memory 234 may store computer readable instructions that, when executed by processor 214 or processor 232, may cause components of internal computing system 210 or external computing system 229, respectively, to perform one or more operations as will be described herein.

Memory 216 and/or memory 234 may represent random access memory (RAM) comprising the main storage of a computer, as well as any supplemental levels of memory, e.g., cache memories, non-volatile or backup memories (e.g., programmable or flash memories), mass storage memory, read-only memories (ROM), etc. In addition, the memory 216 and/or memory 234 may be considered to include storage physically located elsewhere, e.g., cache memory in any computing system communicating with internal computing system 210 or external computing system 229 respectively, as well as any storage device on any computing system in communication the internal computing system 210 and/or external computing system 229 (e.g., a remote storage database, a memory device of a remote computing device, cloud storage, etc.).

Instructions for operating automatic battery test system 202 may be stored on memory 216 and/or memory 234. FIG. 2 shows instructions stored on memory 234, it is understood that instructions may alternatively or additionally be stored on memory 216 without departing from a scope of the disclosure. Instructions included in memory 234 may include a software (SW) check and data collection module 220. Software check and data collection module 220 may be configured to communicate with the BMS of battery system 102 to retrieve battery parameters and provide real-time monitoring as well as evaluate performance of software of battery system 102 stored on the BMS. Additionally, SW check/data collection module 220 may include instructions for opening and closing switches (e.g., line switches 306 and node switches 305) of switch matrix 204 and activating peripheral instruments 205 to collect outputs from, for example, the measurement device 206 and/or power supply/load unit 208 that are indicative of performance of hardware of battery system 102.

Memory 234 may further include a data interpretation module 224. Data interpretation module 224 may be configured to analyze hardware performance via outputs collected via switch matrix 204 from connections of peripheral instruments 205 (e.g., measurement device 206 and/or power supply/load unit 208) with components of battery system 102. As one example, data interpretation module 224 may include a look up table of acceptable value thresholds for each measurement performed as instructed by the SW check/data collection module 220. Data interpretation module 224 may further include instructions to display an output indicative of overall performance of the battery system 102 based on a combination of all the received inputs. In some examples, the output indicative of overall performance of the battery system 102 may be compared to a threshold performance and a binary (e.g., PASS/FAIL) result of testing the battery system 102 may be displayed. In some examples, data interpretation module 224 may include an artificial intelligence (AI) (e.g., machine learning) model trained using examples of outputs associated with hardware and software of acceptable battery systems and of failed battery systems. The AI model may learn acceptable outputs for a plurality of different battery systems and various conditions (e.g., different battery system models and use cases).

Memory 234 may further include a graphic user interface (GUI) module 218. An operator 228 may interact with GUI module 218 via input/output device 212. The operator may interact with the modules of automatic battery test system 202 via GUI module 218. As one example, the operator may initiate automatic testing of battery system 102 via GUI module 218. In one embodiment the SW check/data collection module may be configured to identify a coupled battery system and automatically perform the desired hardware and software tests of battery system 102 when initiated by the operator via the GUI. In this way, it is not demanded that the operator is an expert user who may know the hardware and software configurations for each test. Further, the hardware and software tests may be performed in the same manner for each battery system regardless of the operator 228.

Memory 234 may further include report generation module 226. Report generation module 226 may receive both raw data from SW check/data collection module 220 and from data interpretation module 224. Report generation module 226 may output a battery test result to GUI 218 which is displayed to the operator 228 via input/output device 212. As one example, the battery test result may be a pass or fail result. Additionally or alternatively, report generation module 226 may output a report 112. As described above, report 112 may be a detailed report and may include a pass or fail result in addition to data analysis output by data interpretation module 224. In some example, report 112 may be useful to an expert user who is not the operator 228. Further, the report 112 may include information relevant to troubleshooting battery system 102 if a fail result is received.

Turning now to FIG. 4, a flowchart of an example of a method 400 for automatically testing a battery system, such as battery system 102, using an automatic battery test system, such as automatic battery test system 202 is shown. Steps of method 400 may be at least partially carried out by a processor of a computing system, such as internal computing system 210 and/or external computing system 229 of FIG. 2 based on instructions stored in non-volatile memory.

At 402, method 400 includes coupling the battery system to an automatic battery testing system at a switch matrix. The switch matrix may include a 4×N matrix of electrical connections as described in FIG. 3A or a plurality of matrices coupled in parallel as shown in FIG. 3B. Coupling the battery system to the automatic battery test system may include making a single physical connection between the switch matrix and the battery system. A type of connection may depend on the battery system being tested. For example, the connection may be a AMP multiple contact port (MCP), ITT APD, or the like. The automatic battery testing system may include a plurality of cables to cover a range of types of battery systems and the operator may select an appropriate cable. The automatic battery testing system may include instructions to connect communication and power lines of the battery system to the automatic testing system in a pre-specified order. The pre-specified order may be an order selected to carry out evaluations while maintain a remaining useful life of the battery system.

In some examples, once coupled, the automatic battery test system may include instructions to confirm connections between the automatic battery test system and the battery system are as expected. For example, a CAN BUS line of the battery system may be terminated with a 120 ohm resistance and the automatic battery test system may check for the expected resistance. Connections between the automatic battery test system and peripheral instruments may also be checked, for example if the automatic battery test system is testing for a continuity/short or checking insulation of the battery system.

At 403, method 400 includes determining pre-defined battery tests to be executed. Determining pre-defined battery tests to be executed may be based on a type of battery system being tested, a location of the battery system (in a factory or onsite), a history of the battery (was it overheated? has it been operating for a threshold number of hours?), among others. In some examples, the method 400 may determine pre-defined battery tests to be executed based on an input of an operator to the automatic battery test system via an input of the computing system, or additional tests may be defined by the operator. In further examples, the automatic battery test system may be configured to execute tests for each battery and they may be automatically determined to be the same each time the automatic battery test system is used. In some examples, the computing system may include instructions to determine characteristics of the battery system and automatically determine the pre-defined battery tests based on the characteristics (e.g., from a lookup table).

At 404, method 400 includes automatically utilizing the switch matrix to carry out the determined pre-defined tests. The method may automatically perform step 404 in response to a command from an operator to start a battery test and according to instructions stored in a SW check/data collection module of the automatic battery test system. The automatic battery test system may then automatically utilize the switch matrix by opening and closing switches to couple components of the battery system according to the pre-defined tests. As one example, utilizing the switch matrix may include coupling the peripheral instruments to the battery system and/or to communicatively couple battery system components to the computing system. In this way, each pre-defined battery test is performed and outputs collected by the automatic battery test system. As one example, step 404 may start in response to a command issued via a GUI displayed to the operator. At 405, method 400 includes collecting outputs of the battery test via the switch matrix and communication interface. As one example, outputs of the tests may be collected at the computing system communicatively coupled to the switch matrix via the communication interface. The collected outputs may then be input to perform step 406 as described below.

At 406, method 400 includes interpreting the collected outputs and outputting a result. The result output may convey the performance of the battery system. The output may be based on instructions to interpret the collected results from the battery tests performed at step 404 and collected at step 405. Instructions to output the result may be included in a data interpretation module. As one example, interpreting the result may include to compare outputs collected at step 405 to threshold values and issue one or more PASS/FAIL reports related to performance of the battery. In some examples, the data collected may be mathematically analyzed before comparing with a threshold value. For example, a change in a value over time may be calculated as slope or moving average and may be compared with expected slopes or moving averages. In this way, the results output at step 406 may be automatically interpreted by instructions stored in or sent to the automatic battery test system and not by the operator.

Optionally, at 408, method 400 includes outputting a report. The report may convey to an expert user the tests performed and outputs collected at step 404 in addition to the PASS/FAIL results. As one example, the report may be used to by an expert user to troubleshoot the battery system if a FAIL result is received. Additionally, the report may include interpreted results.

As one example, the battery system tested by the automatic battery test system may be an automotive battery system. In such an example, one of a plurality of tests performed may be to test performance of a pre-charge circuit and main switch of the automotive battery system. The pre-charge circuit may be configured to equalize internal and external battery system potentials with a limited current prior to closure of the main switch. The pre-charge circuit may prevent an in-rush of current to prolong a useful life of the battery system. The automatic battery test system may test function of a pre-charge circuit of an automotive battery system as described below with reference to method 400.

Coupling the automotive battery system to the automatic battery test system at 402 may include coupling the automatic battery test system to the automotive battery system after the automotive battery system is installed in the vehicle. Due to limited accessibility once installed in the vehicle, the portable form factor of the automatic battery test system may allow for coupling after the automotive battery system is installed. In this way, the battery system may be tested for any possible degradation that occurs during installation. The automatic battery test system may perform internal tests to verify a successful connection. For example, the automatic battery test system may check hardware requirements including continuity of connections, lack of shorts, a CAN BUS termination, and/or internal impedance of a printed circuit board assembly of the automatic battery test system to find available signal/power lines. Additionally, the automatic battery test system may check that there is not voltage in non-active electrical connections that are not expected to have voltages. In this way, integrity of both the automotive battery system and automatic battery test system may be protected.

Determining the battery tests at 403 may include determining that the automatic battery test system is coupled to an automotive battery system. A memory of the automatic battery test system may include a plurality of tests and desired order of tests demanded for an automotive battery system. Testing performance of a pre-charge circuit and main switch may be one of the plurality of tests. Testing performance of a crash system of the automotive battery system may also be included in the plurality of tests and is discussed further below.

Automatically opening and closing switches of the switch matrix according to the determined test at 404 may include, in the example of testing a pre-charge circuit, controlling conditions for sending a switch closure command to the pre-charge circuit. For example, communication connection with the BMS may be checked and settings of the battery system operation mode may be checked for being in self-diagnosis mode for operation preventative faults. An impedance-capacitance may be coupled to vehicle side terminals of the automotive battery system to simulate a real charging event. After conditions are set, the automatic battery test system may actuate switches of the switch matrix and peripheral instruments to simultaneously close the pre-charge circuit and measure voltage changes at the battery terminals at timed intervals. For example, the close command may be sent through communications lines such as a CAN BUS and a time reference may be started to measure changes in voltage over time.

Collecting outputs via the switch matrix at 405 may include collecting correlated time and voltage measurements and the measurements may be saved to an internal memory of the automatic battery test system, or alternately to an external computing system coupled to the automatic battery test system. In order to output a result at 406, the automatic battery test system may further mathematically transform the collected outputs. The mathematically transformed values may then be compared to values stored on a look-up table. In the example of the pre-charge circuit, moving averages and loops may be used to find relevant values of the collected voltage and time points. The results of the moving averages/loops may then be compared to a look-up table.

Turning briefly to FIG. 6, a graph 600 of an example of measurements collected by the automatic battery test system during a test of pre-charge circuits of an automotive battery system is shown. Voltage measured by the measurement system is plotted as a function of time. At point A, indicated by line 602, a command to start pre-charge may be sent by the automatic battery test system via the BMS. At point B indicated by line 604, the pre-charge circuit is activated and voltage increases. At point C, indicated by line 606, the main switch is closed and voltage increases further. A voltage and rates of change of voltage may be determined at each of these time points and compared to expected values stored on a look up table.

The result output at 406 may be used by the automatic battery test system to output a pass/fail result of the pre-charge circuit in addition to other tests of the automotive battery system. In some examples, the result of the pre-charge circuit test may be one of many inputs used by the automatic battery test system to determine a pass/fail of the automotive battery system. In some examples, additional details may be provided in a report at 408. For example, the report may include a value of the slope at each of the lines indicated on graph 600. As a further example, graph 600 may be generated as part of a report.

As another example of a test of an automotive battery system, aspects of a crashworthiness of the automotive battery system may be tested. As part of a crash system, the BMS may be configured to respond to a pulse of current (e.g., a crash pulse) indicating that a crash has occurred. Further, the BMS may be configured to not respond to other current pulses that are outside a range of current/time designated as crash pulse.

An example of ranges of pulses received by an automotive battery system is shown in graph 700 of FIG. 7. Graph 700 plots current on the y axis as a function of time on the x-axis. Regions of graph 700 corresponding to ranges of current/times of pulses received by the BMS are delineated. The area of box 702 are ranges of current/times that indicate a crash to the BMS, therefore a reaction from the BMS is demanded. The areas of boxes 704 are ranges of current/times that demand a non-critical response of the BMS. The areas of boxes 706 are current/times that do not demand a response of the BMS.

The automatic battery test system may selectively open/close switches of the switch matrix to couple a power supply system configured to generate a plurality of current pulses over a range of currents/times to lines of the automotive battery system configured to receive crash signals. The response of the BMS may be monitored by the automatic battery test system and validated based on a demanded response as shown in graph 700. In this way, performance of the BMS in crash scenarios and other scenarios may be tested.

The technical effect of method 400 is to determine a performance of a battery system in a clear and repeatable manner using the automatic battery testing system. The method 400 may be performed by an operator without knowledge of the specific battery test methods or desired method of data analysis. In this way, tests of battery systems may be performed by a wide range of individuals and in conditions outside of a lab or manufacturing setting. Further, the battery testing may be uniform and repeatable across each operator. Uniformity in testing may aid in future added features and benefits to battery systems as well as reliably determining non-performing battery systems before degradation of the battery system causes additional cascading issues.

The disclosure also provides support for an automatic battery test system for a battery system, comprising, a switch matrix configured to couple to the battery system and comprised of rows and columns of electrical connections and switches configured to re-route power and signals through the electrical connections, a peripheral instrument coupled to the battery system via the switch matrix, a communication interface coupled to the switch matrix, and a computing system coupled to the switch matrix via the communication interface. In a first example of the system, the peripheral instrument is one or more of a measurement device or a power supply/load unit. In a second example of the system, optionally including the first example, the measurement device is one or more of a digital multimeter or a hipot tester. In a third example of the system, optionally including one or both of the first and second examples, a number of columns of electrical connections is greater than or equal to a number of rows of electrical connections. In a fourth example of the system, optionally including one or more or each of the first through third examples, the communication interface is a serial communication protocol. In a fifth example of the system, optionally including one or more or each of the first through fourth examples, the computing system is an internal computing system. In a sixth example of the system, optionally including one or more or each of the first through fifth examples, the computing system is an external computing system. In a seventh example of the system, optionally including one or more or each of the first through sixth examples, the switches include line switches positioned in-line with each of the columns. In a eighth example of the system, optionally including one or more or each of the first through seventh examples, the switches include node switches positioned at each intersecting node of the rows and columns of electrical connections.

The disclosure also provides support for a method, comprising: coupling a battery system to a switch matrix of an automatic battery test system, wherein the switch matrix includes a plurality of switches and is coupled to a peripheral instrument determining tests to be executed by the automatic battery test system, automatically utilizing the switch matrix to selectively couple components of the battery system to the switch matrix and collecting outputs from the peripheral instrument at a computing system coupled to the battery system via the switch matrix and a communication interface, interpreting the collected outputs, and outputting a result indicative of a performance of the battery system. In a first example of the method, coupling the battery system includes automatically coupling components of the battery system in a pre-specified order. In a second example of the method, optionally including the first example, coupling the battery system includes determining a voltage is not present across non-active electrical connections. In a third example of the method, optionally including one or both of the first and second examples, interpreting the collected outputs is performed automatically by comparing the collected outputs to expected values. In a fourth example of the method, optionally including one or more or each of the first through third examples, determining tests includes automatically determining tests based on identifying a type of battery system coupled to the automatic battery test system. In a fifth example of the method, optionally including one or more or each of the first through fourth examples, interpreting the collected outputs includes mathematically transforming the collected outputs. In a sixth example of the method, optionally including one or more or each of the first through fifth examples, the battery system is an automotive battery system installed in a vehicle.

The disclosure also provides support for an automatic battery test system for a battery system, comprising, a peripheral instrument, a switch matrix including a matrix of electrical connections and switches, the switches configured to electrically couple to the battery system to the peripheral instrument, a computing system coupled to the switch matrix, the computing system including instructions stored on non-volatile memory that when executed cause the computing system to: collect outputs of the peripheral instrument and outputs of a battery management system of the battery system, interpret the collected outputs to determine a performance of the battery system, output a result to an output device of the computing system, indicating battery is above or below a threshold performance. In a first example of the system, the switch matrix is a 4×N matrix of electrical connections, and wherein N is at least 4. In a second example of the system, optionally including the first example, the switch matrix includes a plurality of switch matrices coupled in parallel. In a third example of the system, optionally including one or both of the first and second examples, the instructions further include to output a report including the collected outputs and interpreted results.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. An automatic battery test system for a battery system, comprising:
a switch matrix configured to couple to the battery system and comprised of rows and columns of electrical connections and switches configured to re-route power and signals through the electrical connections;
a peripheral instrument coupled to the battery system via the switch matrix;
a communication interface coupled to the switch matrix; and
a computing system coupled to the switch matrix via the communication interface.

2. The automatic battery test system of claim 1, wherein the peripheral instrument is one or more of a measurement device or a power supply/load unit.

3. The automatic battery test system of claim 2, wherein the measurement device is one or more of a digital multimeter or a hipot tester.

4. The automatic battery test system of claim 1, wherein a number of columns of electrical connections is greater than or equal to a number of rows of electrical connections.

5. The automatic battery test system of claim 1, wherein the communication interface is a serial communication protocol.

6. The automatic battery test system of claim 1, wherein the computing system is an internal computing system.

7. The automatic battery test system of claim 1, wherein the computing system is an external computing system.

8. The automatic battery test system of claim 1, wherein the switches include line switches positioned in-line with each of the columns.

9. The automatic battery test system of claim 1, wherein the switches include node switches positioned at each intersecting node of the rows and columns of electrical connections.

10. A method, comprising:
coupling a battery system to a switch matrix of an automatic battery test system, wherein the switch matrix includes a plurality of switches and is coupled to a peripheral instrument;
determining tests to be executed by the automatic battery test system;
automatically utilizing the switch matrix to selectively couple components of the battery system to the switch matrix and collecting outputs from the peripheral instrument at a computing system coupled to the battery system via the switch matrix and a communication interface;
interpreting the collected outputs; and
outputting a result indicative of a performance of the battery system.

11. The method of claim 10, wherein coupling the battery system includes automatically coupling components of the battery system in a pre-specified order.

12. The method of claim 10, wherein coupling the battery system includes determining a voltage is not present across non-active electrical connections.

13. The method of claim 10, wherein interpreting the collected outputs is performed automatically by comparing the collected outputs to expected values.

14. The method of claim 10, wherein determining tests includes automatically determining tests based on identifying a type of battery system coupled to the automatic battery test system.

15. The method of claim 10, wherein interpreting the collected outputs includes mathematically transforming the collected outputs.

16. The method of claim 10, wherein the battery system is an automotive battery system installed in a vehicle.

17. An automatic battery test system for a battery system, comprising:
a peripheral instrument;
a switch matrix including a matrix of electrical connections and switches, the switches configured to electrically couple the battery system to the peripheral instrument;
a computing system coupled to the switch matrix; the computing system including instructions stored on non-volatile memory that when executed cause the computing system to:
collect outputs of the peripheral instrument and outputs of a battery management system of the battery system;
interpret the collected outputs to determine a performance of the battery system; and
output a result to an output device of the computing system, indicating battery is above or below a threshold performance.

18. The automatic battery test system of claim 17, wherein the switch matrix is a 4×N matrix of electrical connections, and wherein N is at least 4.

19. The automatic battery test system of claim 17, wherein the switch matrix includes a plurality of switch matrices coupled in parallel.

20. The automatic battery test system of claim 17, wherein the instructions further include to output a report including the collected outputs and interpreted results.
